(19) United States
(12) Patent Application Publication
(10) Pub. No.: US 2013/0077259 A1
(43) Pub. Date: Mar. 28, 2013

(54) ELECTRONIC DEVICE WITH DOUBLE CIRCUIT BOARDS

(71) Applicants: GUANG-YI ZHANG, Shenzhen City (CN); MENG-QI ZHANG, Shenzhen City (CN)

(72) Inventors: GUANG-YI ZHANG, Shenzhen City (CN); MENG-QI ZHANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/298,307

(22) Filed: Nov. 17, 2011

(30) Foreign Application Priority Data
Sep. 22, 2011 (CN) 201110283682.8

(51) Int. Cl. H05K 7/16; H05K 1/14

(52) U.S. Cl. 361/725; 361/736

(57) ABSTRACT

A double circuit board module includes a bracket, a pivot rack pivotably mounted to the bracket, a first circuit board fixed to the bracket, and a second circuit board fixed to the pivot rack. After the pivot rack is pivoted away from the bracket, the first circuit board is exposed.

### BACKGROUND

1. Technical Field

The present disclosure relates to electronic devices, and particularly, to an electronic device with double circuit boards.

2. Description of Related Art

Electronic devices, such as servers, usually use double circuit boards to expand functions. However, the double circuit boards often make the cable arrangement and repairing the electronic device difficult.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an electronic device, in accordance with an embodiment, wherein the electronic device includes a double circuit board module.

FIG. 2 is an exploded, isometric view of the double circuit board module of FIG. 1.

FIG. 3 is an inverted view of FIG. 2.

FIG. 4 is an assembled, isometric view of FIG. 2.

FIG. 5 shows a using state of the double circuit board module of FIG. 4.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

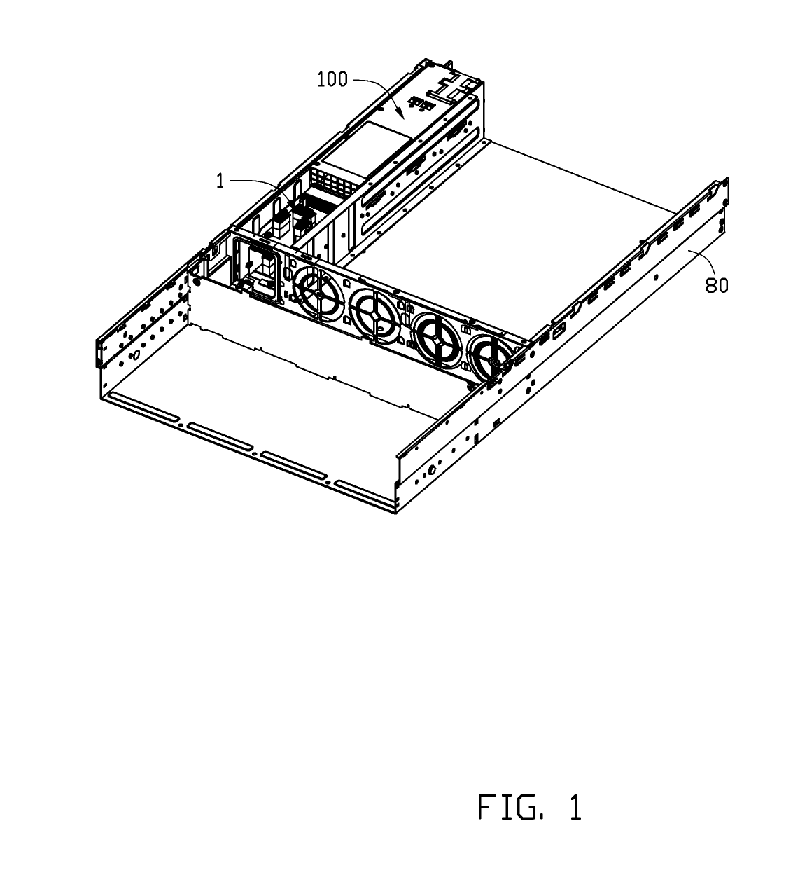

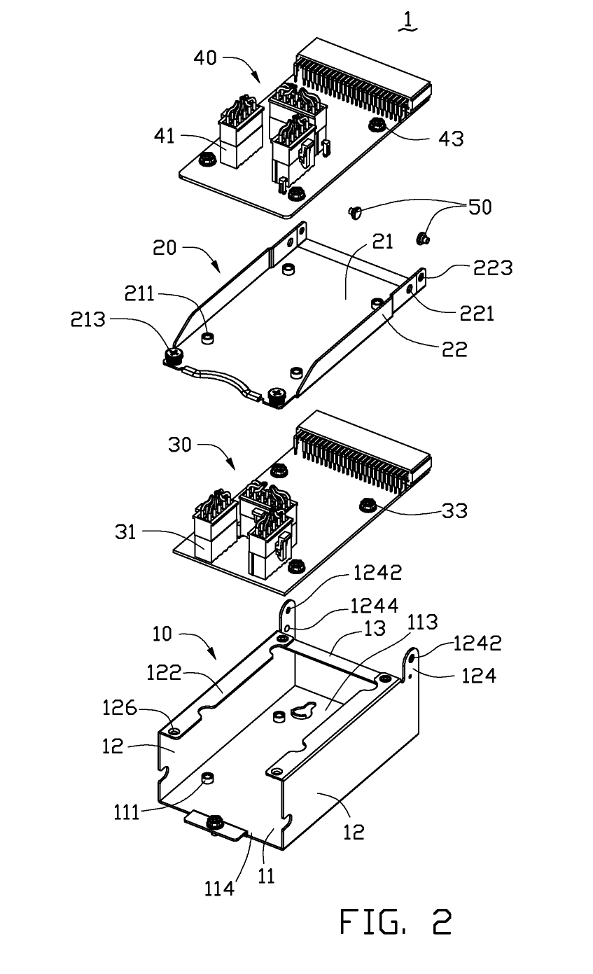

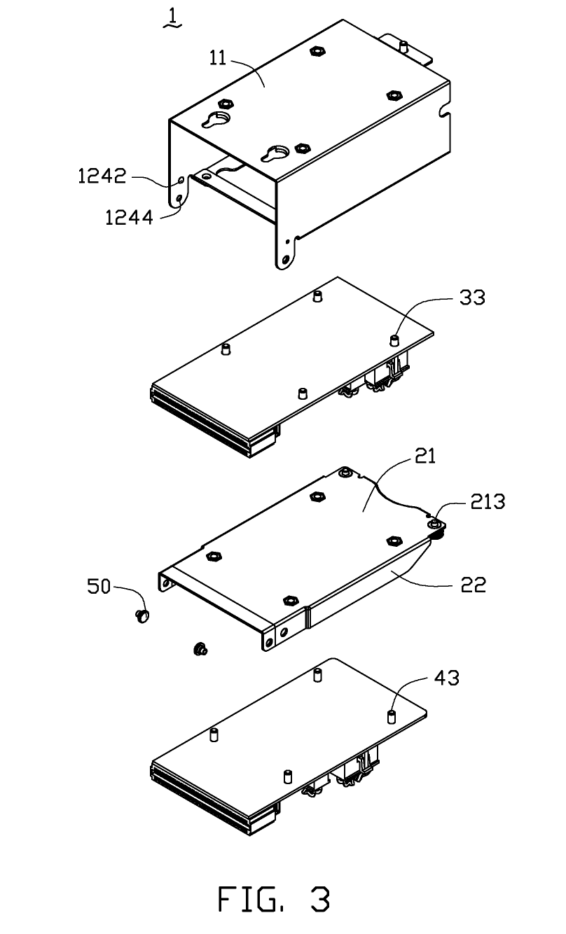

Referring to FIGS. 1 to 3, an exemplary embodiment of an electronic device 100 includes a chassis 80, and a double circuit board module 1 accommodated in the chassis 80. The double circuit board 1 includes a bracket 10, a pivot rack 20, a first circuit board 30, a second circuit board 40, and two fasteners 50.

The bracket 10 includes a rectangular base plate 11, and two side plates 12 perpendicularly extending up from two opposite sides of the base plate 11. A plurality of rods 111 protrudes from the base plate 11. The base plate 11 includes a first end 113 and a second end 114 opposite to the first end 113. A supporting piece 122 extends inward from a top of each side plate 12 toward the other side plate 12. A connecting piece 13 is connected between first ends of the supporting pieces 122 adjacent to the first end 113. A pivot piece 124 extends up from the first end of each side plate 12 at an outer side of the connecting piece 13. Each pivot piece 124 defines a pivot hole 1242. A raised portion 1244 protrudes from an inner surface of each pivot piece 124 adjacent to the pivot hole 1242. The pivot pieces 124 are extended out of the supporting pieces 122. A screw hole 126 is defined in a second end of each supporting piece 122 away from the connecting piece 13.

The pivot rack 20 includes a bottom wall 21 and two sidewalls 22 perpendicularly extending up from two opposite sides of the bottom wall 21. A plurality of rods 211 protrude from the bottom wall 21. Two thumbscrews 213 extend through a first end of the bottom wall 21. The sidewalls 22 each define a through hole 221 and a positioning hole 223 away from the first end of the bottom wall 21.

The first circuit board 30 includes a plurality of connectors 31. A plurality of screws 33 extends through the first circuit board 30. The second circuit board 40 includes a plurality of connectors 41. A plurality of screws 43 extends through the second circuit board 40.

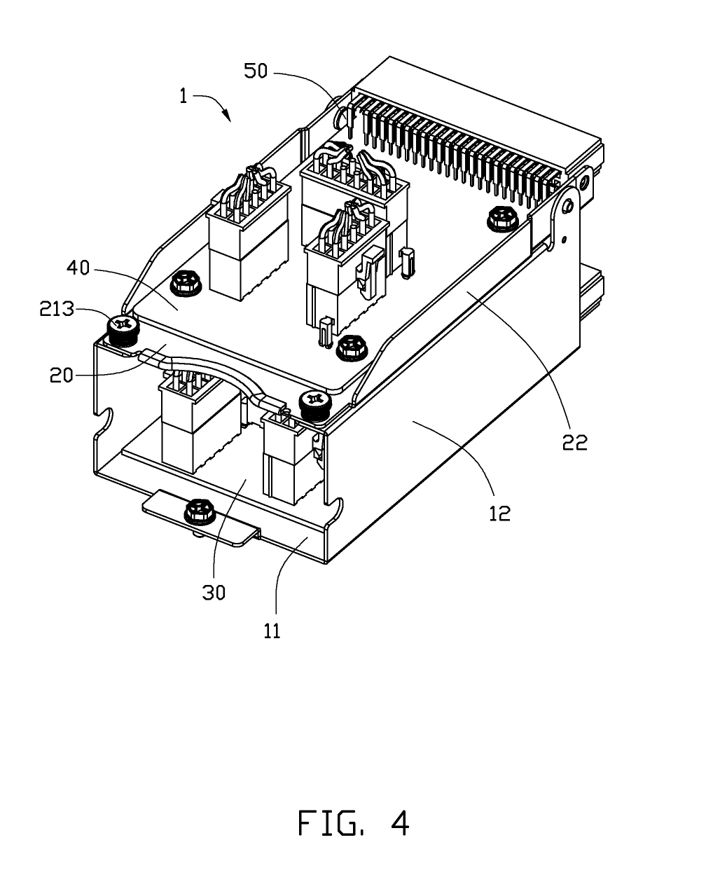

Referring to FIG. 4, in assembling the double circuit board module 1, the first circuit board 30 is placed in the bracket 10 and is fixed to the base plate 11 through the screws 33 screwing into the rods 211. The pivot rack 20 is supported on the supporting pieces 122 and sandwiched between the pivot tabs 124, thereby being spaced from the base plate 11. The fasteners 50 extend through the through holes 221 and the pivot holes 1242 respectively to pivotably attach the pivot rack 20 to the bracket 10. The thumbscrews 213 are screwed into the screw holes 126 respectively. The second circuit board 40 is fixed to the bottom wall 21 through the screws 43 screwing into the rods 411.

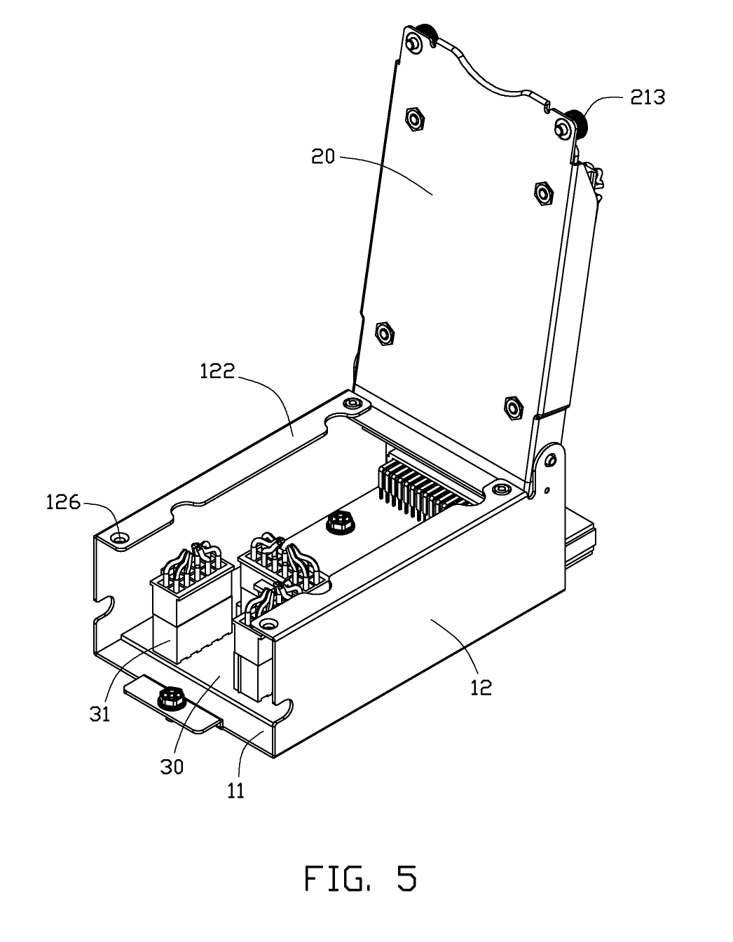

Referring to FIG. 5, when need to operate the connectors 31 of the first circuit board 30, the thumbscrews 213 are released from the screw holes 126 to rotate the pivot rack 20 relative to the bracket 10, until the raised portions 1244 engage in the positioning holes 223. Thereby, the first circuit board 30 is exposed to be conveniently operated.

It is believed that the present embodiments and theirs advantages will be understood from the foregoing description, and they will be apparent that various changes may be made thereto without departing from the spirit and scope of the description or sacrificing all of their material advantages, the examples hereinbefore described merely being exemplary embodiment.

What is claimed is:

1. A double circuit board module comprising:
a bracket;
a pivot rack pivotably mounted to the bracket;
a first circuit board fixed to the bracket; and
a second circuit board fixed to the pivot rack.

2. The double circuit board module of claim 1, wherein the bracket comprises a base plate and two side plates extending up from two opposite sides of the base plate, the pivot rack is pivotably attached to first ends of the side plates, the first circuit board is fixed to the base plate.

3. The double circuit board module of claim 2, wherein a plurality of rods protrudes from the base plate, the first circuit board is fixed to the base plate through a plurality of screws extending through the first circuit board to screw into the rods.

4. The double circuit board module of claim 2, wherein the pivot rack comprises a bottom wall, a plurality of rods protrude from the bottom wall, the second circuit board is fixed to the bottom wall through a plurality of screws extending through the second circuit board to screw into the rods.

5. The double circuit board module of claim 4, wherein a pivot piece extends from the first end of each side plate of the bracket, the pivot piece defines a pivot hole, the pivot rack comprises two sidewalls extending from two opposite sides of the bottom wall, each of the sidewalls defines a through hole, two fasteners extend through the through holes and the pivot holes respectively to pivotably attach the pivot rack to the bracket.

6. The double circuit board module of claim 5, wherein each of the sidewalls defines a positioning hole adjacent to the through hole, a raised portion protrudes from each of the pivot pieces adjacent to the pivot hole, the raised portion is engagable in the positioning hole to position the pivot rack after the pivot rack is pivoted away from the bracket.

7. The double circuit board module of claim 6, wherein a supporting piece extends inward from a top of each of the side plates to support the pivot rack.

8. The double circuit board module of claim 7, wherein each of the supporting piece defines a screw hole away from the first end of the side plates, two screws extend through the bottom wall of the pivot rack and are engagable in the corresponding screw holes.

9. An electronic device comprising:
a chassis; and
a double circuit board module comprising:
a bracket comprising a base plate;
a pivot rack pivotably mounted to the bracket and comprising a bottom wall spaced from the base plate;
a first circuit board fixed to the base plate of the bracket; and
a second circuit board fixed to the bottom wall of the pivot rack.

10. The electronic device of claim 9, wherein the bracket comprises two side plates extending up from two opposite sides of the base plate, the pivot rack is pivotably attached to corresponding ends of the side plates.

11. The electronic device of claim 10, wherein a plurality of rods protrudes on the base plate, the first circuit board is fixed to the base plate through a plurality of screws extending through the first circuit board to screw into the rods.

12. The electronic device of claim 10, wherein a plurality of rods protrude from the bottom wall, the second circuit board is fixed to the bottom wall through a plurality of screws extending through the second circuit board and screwing into the rods.

13. The electronic device of claim 12, wherein a pivot piece extends up from the end of each of the side plates of the bracket, each pivot piece defines a pivot hole, the pivot rack comprises two sidewalls extending from two opposite sides of the bottom wall, each of the sidewalls defines a through hole, two fasteners extend through the through holes and the pivot holes respectively to pivotably attach the pivot rack to the bracket.

14. The electronic device of claim 13, wherein each of the sidewalls defines a positioning hole adjacent to the through hole, a raised portion protrudes on each of the pivot pieces adjacent to the pivot hole, the raised portion is engagable in the positioning hole to position the pivot rack after the pivot rack is pivoted away from the bracket.

15. The electronic device of claim 14, wherein a supporting piece extends inward from a top of each of the side plate to support the pivot rack.

16. The electronic device of claim 15, wherein each of the supporting pieces defines a screw hole, two screws extend through the bottom wall of the pivot rack and are engagable in the corresponding screw holes.
